(19) United States
(12) Patent Application Publication
(10) Pub. No.: US 2007/0033465 A1
(43) Pub. Date: Feb. 8, 2007

(54) Apparatus and method for a single wire interface between a intergated circuit and JTAG test and emulation apparatus

(76) Inventor: Craig B. Greenberg, Rowlett, TX (US)

Correspondence Address: TEXAS INSTRUMENTS INCORPORATED, P O BOX 655474, M/S 3999, DALLAS, TX, 75265, US

(21) Appl. No.: 11/473,667

(22) Filed: Jun. 23, 2006

Related U.S. Application Data
(60) Provisional application No. 60/699,938, filed on Jul. 15, 2005.

(51) Int. Cl. G01R 31/28

(52) U.S. Cl. 714/731

(57) ABSTRACT

A single conducting path provides communication between a JTAG unit and a JTAG TAP controller. The data is communicated between the two units using time-division multiplexing. Three time slots are allocated to data-in, to data-out and to JTAG control signals. Two of the time-division multiplexing slots exchange data by having one logic signal state defined by the supply voltage and the second logic signal state defined by the voltage level high than the supply voltage. The third time-division multiplexing slot has the logic signal state defined by the presence or absence of signal occurring within the time slot.

This application claims the benefit of Provisional Application Ser. No. 60/699,938, entitled “Low Cost Single Wire Interface for Test and Emulation Purposes”, filed on Jul. 6, 2005.

### BACKGROUND OF THE INVENTION

1. Field of the Invention

This invention relates generally to the test and emulation of integrated circuits and, more particularly, to the test and emulation of integrated circuits using the JTAG protocol.

2. Background of the Invention

the JTAG protocol has become one of the premier tools in the test, debug, and emulation of integrated circuits. In a process referred to as boundary scan, a host processor can initialize the state of an integrated circuit and can determine the state of the integrated circuit after a predetermined number of clock cycles or upon detection of a predetermined event.

The JTAG protocol includes five signal groups that are exchanged between the emulation unit and the target processor. The TCK signals synchronize the internal state machine operations. The TCK, TMS, TDI, TDO single signals are mode select signals that are sampled on the rising edge of a TCK, TMS, TDI, TDO single signal to determine the next state. The TCK, TMS, TDI, TDO single signals are the test data-in signals that are at the rising edge a TCK, TMS, TDI, TDO single signals and are shifted into the target processor test or programming logic circuits when the internal state machine is the correct state. The TCK, TMS, TDI, TDO single signals are test data-out signals and are data shifted out of the target processor's test or programming logic and are valid on the falling edge of the TCK, TMS, TDI, TDO single signals when the internal state of the state machine is in the correct state. The TRST signals (optional) are reset signals that, when driven low, resets the internal state machine.

Typically, four or five pins on the integrated circuit chip that includes the target processor are dedicated to transfer of signals between the JTAG unit and the target processor. Referring now to FIG. 1, a host processing unit (not shown) controls the activity of a JTAG unit 11. The host processing unit controls the test procedures to be implemented and analyses the results of the test procedures. The JTAG unit 11 exchanges the TCK, TMS, TDI, TDO single signals, the TCK, TMS, TDI, TDO single signals, the TCK, TMS, TDI, TDO single signals, and the TCK, TMS, TDI, TDO single signals with the JTAG TAP (test access port) unit 121 in the target device 12. These signals are transferred through pins forming part of the integrated circuit 12. The JTAG TAP unit 121 exchanges signals with an emulation unit 122. The emulation unit exchanges signals with a core logic portion 123.

As the number and complexity of components/gates in target device 12 has continued to increase, competition for use of the interface pins has expanded. The competition has only gotten more intense with each new product.

A need has therefore been felt for apparatus and an associated method having the feature of providing additional pins associated with an integrated circuit for the exchange of signals between the integrated circuit and external apparatus. It would be yet another feature of the apparatus and associated method to provide an interface between a JTAG unit and an emulation unit in the target device. It would be still another feature of the apparatus and associated method to provide exchange JTAG signals over a single conductor using time-division multiplex protocols.

### SUMMARY OF THE INVENTION

The foregoing and other features are accomplished, according the present invention by providing an interface unit associated with the JTAG unit that creates a single set of multiplexed signals that can be exchanged with an interface device in the target device. The signals are formatted to provide all of the information needed for the JTAG TAP unit to test and debug the core logic using the JTAG boundary value protocols. In addition to the multiplexing of the JTAG control signals, the interface apparatus uses an additional voltage level to transmit the TDI from the JTAG unit to the interface unit in the target device.

Other features and advantages of present invention will be more clearly understood upon reading of the following description and the accompanying drawings and the claims.

### BRIEF DESCRIPTION OF THE DRAWINGS

FIG. 1 is a block diagram of apparatus for the test and debug of core logic of an integrated circuit using the JTAG protocol according to the prior art.

FIG. 2 is a block diagram of apparatus for the test and debug of core logic of an integrated circuit according to the present invention.

FIG. 3 illustrates the partition of the signals in the time-division multiplex protocol according to the present invention.

FIG. 4 illustrates a circuit for the detection of selected signal levels in the time-division multiplex protocol of FIG. 3 according to the present invention.

### DESCRIPTION OF THE PREFERRED EMBODIMENT

### 1. Detailed Description of the Figures

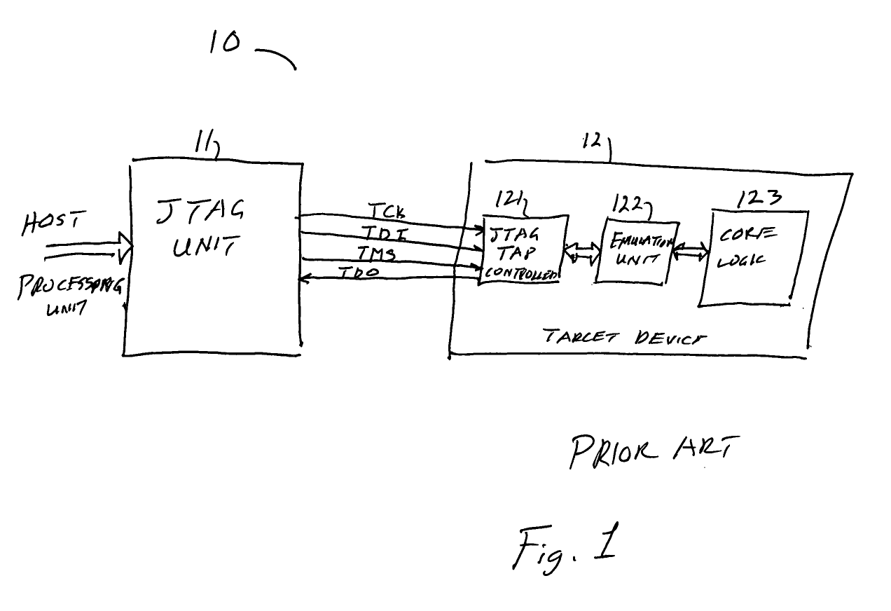

FIG. 1 has been described with respect to the related art.

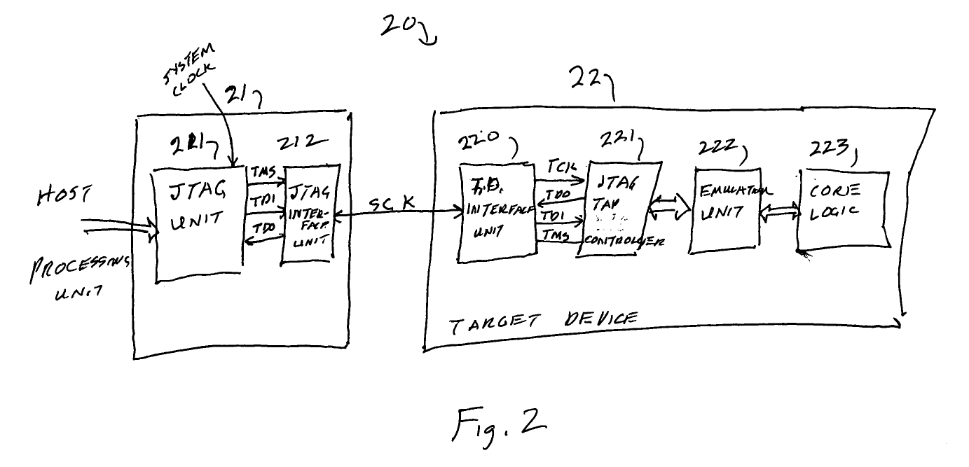

Referring next to FIG. 2, is the block diagram of a JTAG unit and target device test configuration 20 according to the present invention. The JTAG unit 211 exchanges signals with and is controlled by a host processing unit (not shown). The JTAG unit 211 exchanges the TMS signals, the TDO signals and the TDI signals with the JTAG interface unit 212. The JTAG interface unit 212 exchanges SCK signals with the I.C. interface unit 220, the T.D. interface unit 220 being a part of the target device 22. The SCK signals are exchanged over a single conducting path and are coupled to the target device 22 by a single pin. The T.D. interface unit exchanges TCK signals, TMS signals, TDI signals and the TDO signals with the JTAG TAP controller 221. The JTAG TAP controller 221 exchanges signals with the emulation unit 222. The emulation unit 223 exchanges signals with the core logic 223.

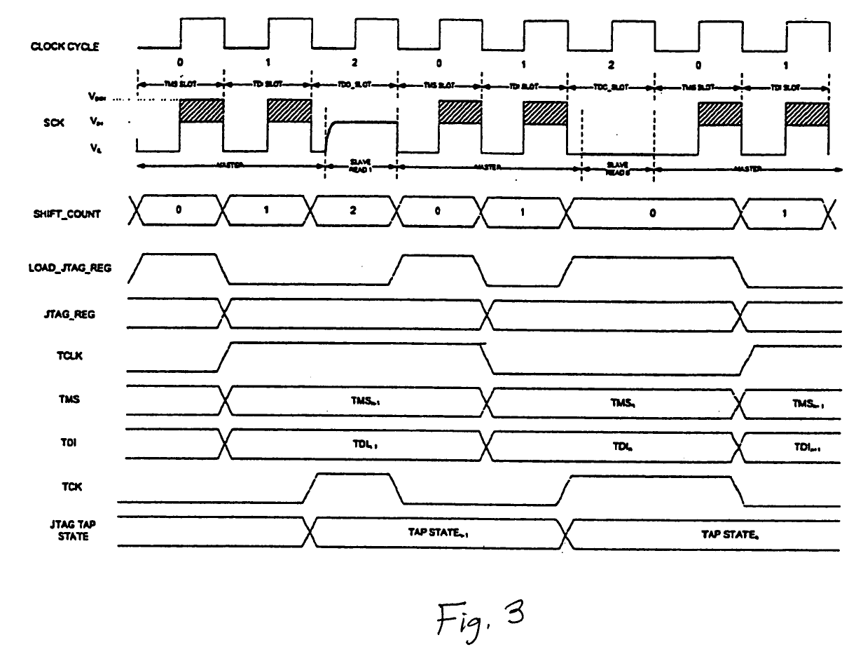

Referring to FIG. 3, the basic timing for the serial interface according to the present invention is shown. The serial communication uses time division multiplexing. Three time slots are allocated TMS_SLOT, TDI_SLOT, and TDO_SLOT. These slots are indicated under the clock cycle diagram in FIG. 3. Data from JTAG unit is written between two logic high states during the high time of the SCK clock cycle. These two levels are referred to as V_{IH} and V_{IHH}. The V_{IH} level never exceeds the logic high level for normal device operation. In the case of CMOS operation, this voltage is typically the provided by the upper supply rail. The V_{IHH} level can exceed the upper supply rail voltage. These voltages are modulated by the incoming data stream. To write a logic “1”, the JTAG unit drives the SCK line to the V_{IHH} voltage level during the high cycle. To write a logic “0”, the JTAG unit drives the SCK line to the logic high (V_{IH}) level. Circuitry in the T.D. interface unit determines when the V_{IHH} signal is present and will store the associated data on the falling edge of the SCK signal. Because the SCK is clocked by the JTAG unit, a good time-base is formed with each falling edge, thereby allowing for relatively high speed data transfer.

The SCK signal is set to input both on the TMS slot and the TDI slot. Internally to the target device, the serial SDATA signal stream is shifted into a two bit register at each falling edge of the SCK clock. During the TDO_SLOT, the shift register is disabled. At the end of three cycles, the serial shift register is transferred into a two bit register. The contents of this register are then entered in the JTAG TAP controller.

FIG. 3 also includes some of the internal signals in the target device. The SHIFT_COUNT signal keeps track of the current clock cycle. The JTAG_REG signal is the two bit register that stores the parallel JTAG commands. This register is updated each time SHIFT_COUNT reaches zero. Note that the TCK signal for the JTAG TAP controller is delayed one cycle from the JTAG_REG update as required. Therefore, the JTAG TAP controller state changes at each rising edge of the TCK signal. The TCLK signal represents the test clock signal. The value of the TCLK signal value is determined by writing a “1” or a “0” during the TDI_SLOT during the Run-Test-Idle of the JTAG algorithm.

Referring once again to FIG. 3, the TDO signal stream is allocated one time slot. The JTAG interface unit releases SCK signal at the end of the TDI slot, the release being triggered by the falling edge of the SCK signal. Once the SCK signal is released, TDO data can be placed on the SCK conductor from the T.D. interface device. Two possibilities can be considered. The first case occurs when TDO data is a high logic level, referred to in FIG. 3 as “SLAVE READ 1. In this case, the T.D. interface unit will drive the SCK conductor to a logic signal high. The SCK conducting path is driven actively for a predetermined period of time, the period of time determined by the parameters of one-shot multi-vibrator. The use of a one shot component allows for a fast transition of the SCK signal under heavy loads. The one shot component is required because no SCK signal is available during the TDO_SLOT to indicate when the T.D. interface unit is to be disabled. The one shot component automatically disables the T.D. interface unit after a set period of time. The JTAG interface unit has a weak signal holder to prevent the SCK line form floating. Therefore, once the signal on the SCK conductor is released, the last previously driven value will be maintained. As shown in FIG. 3, the JTAG interface unit is enabled at the end of the TDO_SLOT. For the case when TDO data is a logic high signal, this signal causes the SCK conductor to transition from high to a logic low signal. For the case when the TDO signal is a logic low signal, (“SLAVE READ”), the T.D. interface unit does not actually drive the SCK conducting path. The bus holder simply maintains the logic low signal imposed by the JTAG interface unit. In this case, no high to low transition is imposed on the SCK conducting path during the TDO_SLOT. Apparatus inside the T.D. interface unit handles both cases to ensure proper shifting of the data into the internal two bit register.

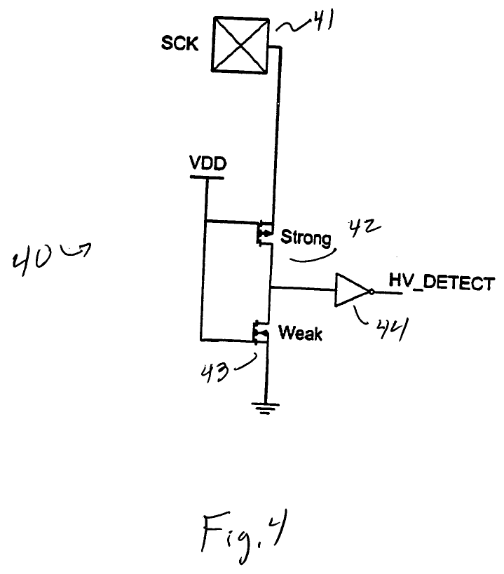

Referring to FIG. 4, detection apparatus 40 for the SCK signals by the T.D. interface unit is shown. As discussed before, the lower voltage is the supply (rail) voltage V_{DD}. The SCK conductor is coupled through a strong p-channel FET 42 and a weak n-channel FET 43 to ground potential. An amplifier 44 is coupled between the p-channel FET 42 and the n-channel FET 43. The V_{DD} voltage is coupled to the control terminal of both FET devices. At normal input voltages the p-channel FET 42 is not turned on. Once the signal on the SCK conductor exceeds the threshold voltage above V_{DD}, the p-channel begins to conduct. The process for fabricating the components must be selected to provide for the higher voltages. For mixed mode components, e.g., 3.3V/1.8V systems, this interface circuit is easily implemented. The SCK conductor can be switched between 1.8V and 3.3V. The I/O components are implemented with 3.3V tolerant transistors.

### 2. Operation of the Preferred Embodiment

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

What is claimed is:

1. A method of transferring signals over a single conducting path, the method comprising:
defining a repeating sequence of time slots in a time-division multiplexing format;
defining a first logic state in a one time slot of the sequence of time slots by a voltage generally equal to the supply voltage, defining second logic state in the one time slot by a voltage exceeding the supply voltage; and
defining a first logic state in a second time slot of the sequence of time slots by the presence of voltage within the time slot.

2. The method as recited by claim 1, wherein the signal transferred over the single conducting path are JTAG signals.

3. The method as recited in claim 2 wherein the one time slot transfers JTAG data-in signals.

4. The method as recited in claim 1 wherein the second time slot transfers the JTAG data out signals.

5. The method as recited in claim 1 wherein a third time slot in the sequence of time slots functions in the manner of the one time slot and transfers JTAG control signals during the time slot.

6. The method as recited in claim 1 wherein one of the states of a logic signal in the second time slot is generated by a one shot multivibrator.

7. A system for testing a target processor, the system comprising:
a JTAG unit; and
a JTAG TAP unit exchanging signals with the JTAG unit by means of single conductor, the JTAG TAP unit exchanging control signals with the target processor.

8. The system as recited in claim 7 wherein exchange of signals over the single conductor includes a sequence of time-division multiplexed time slots.

9. The system as recited in claim 8 wherein a one of the sequence of time-division multiplexed time slots transfer a data-in signal sequence from the JTAG unit to the JTAG TAP unit, and wherein a second of the sequence of time-division multiplexed time slots transfer a data-out sequence of signals from the JTAG TAP unit to the JTAG unit.

10. The system as recited in claim 9 wherein a one time slot transfers data wherein a voltage level at approximately the power supply level indicates a first logic state and a voltage level above the power supply indicates a second logic state.

11. The system as recited in claim 9 wherein a second time slot transfers data wherein a null voltage level indicates a first logic state and a second voltage level indicates a second logic state.

12. The system as recited in claim 11 wherein the second volt5age level is generated during the second time slot by a one shot multivibrator.

13. The system as recited in claim 9 wherein a third of the sequence of time-division multiplexed time slots transfer JTAG control signals to the JTAG TAP controller.

14. In a JTAG test and diagnostic system for test a target processor, wherein data and control signals are exchanged between a JTAG unit and a JTAG TAP controller over a single conductor, the data and control signals being transfer by a predetermined protocol, the protocol comprising:
a series of time slots, the series of time slots being divided into sequences time slots including;
a one of the time slots in each sequence of time slots transferring JTAG data-in signals,
a second of the time slots in each sequence of time slots transferring JTAG data-out signals, an
a third of the time slots in each sequence of time slots transferring JTAG control signals.

15. The protocol as recited in claim 14 wherein, in a first time slot and a third time slot, a logic state is determined by the relationship of the voltage applied to the conductor relative to a supply voltage.

16. The protocol as recited in claim 14 wherein a logic state is determined by the presence or absence of a preselected voltage during the time slot.
